(19) United States
(12) Patent Application Publication
(10) Pub. No.: US 2015/0167151 A1
(43) Pub. Date: Jun. 18, 2015

(54) CARRIER SYSTEMS FOR INTRODUCING MATERIALS INTO MATERIAL PROCESSING SYSTEMS

(71) Applicant: HZO, Inc., Draper, UT (US)

(72) Inventors: James Dempster, Reno, NV (US); Jason Maynard, Salt Lake City, UT (US)

(21) Appl. No.: 14/634,034

(22) Filed: Feb. 27, 2015

Related U.S. Application Data
(63) Continuation-in-part of application No. 14/445,628, filed on Jul. 29, 2014.
Application No. 14/445,628 is a continuation-in-part of application No. 29/482,760, filed on Feb. 21, 2014.
Application No. 29/482,760 is a continuation-in-part of application No. 29/484,069, filed on Mar. 5, 2014.
Application No. 29/484,069 is a continuation-in-part of application No. 29/491,643, filed on May 22, 2014.
Application No. 29/491,643 is a continuation-in-part of application No. 13/737,737, filed on Jan. 9, 2013.
Application No. 13/737,737 is a continuation-in-part of application No. 29/484,067, filed on Mar. 5, 2014.
(60) Provisional application No. 61/946,709, filed on Mar. 1, 2014.
(60) Provisional application No. 61/585,150, filed on Jan. 10, 2012.
(60) Provisional application No. 61/946,709, filed on Mar. 1, 2014.

(51) Int. Cl. C23C 14/24

(52) U.S. Cl. CPC C23C 14/243

(57) ABSTRACT

In various aspects and embodiment, the present disclosure relates to a carrier system for receiving and holding precursor material. The carrier system may be used within a material processing system for forming protecting coatings on a substrate. The carrier system may comprise a carrier including a plurality of receptacles. The carrier system may further include a plurality of cups, each cup configured to be removably positioned with a receptacle of the carrier.

### CROSS REFERENCE TO RELATED APPLICATION

This application claims the benefit of priority under 35 U.S.C. §119(e) to U.S. Provisional Application No. 61/946,709, filed on Mar. 1, 2014 and titled MATERIAL PROCESSING SYSTEMS INCLUDING A CARRIER SYSTEM, CARRIER SYSTEMS FOR INTRODUCING PRECURSOR MATERIALS INTO MATERIAL PROCESSING SYSTEMS, CARRIERS AND CUPS OF A CARRIER SYSTEM, AND ASSOCIATED METHODS (“the '709 Provisional Application”).

This application is a continuation-in-part of U.S. Design Patent Application No. 29/484,067, filed on Mar. 5, 2014 and titled BOAT FOR USE IN A MATERIAL DEPOSITION APPARATUS (“the '067 Design Application”).

This application is a continuation-in-part of U.S. patent application Ser. No. 14/445,628, filed on Jul. 29, 2014 and titled BOATS CONFIGURED TO OPTIMIZE VAPORIZATION OF PRECURSOR MATERIALS BY MATERIAL DEPOSITION APPARATUSES (“the '628 Application”).

The '628 Application is a continuation-in-part of the following applications: (i) U.S. Design Patent Application No. 29/491,643, filed on May 22, 2014 and titled “BOAT FOR A DEPOSITION APPARATUS,” (“the '643 Design Application”); (ii) U.S. Design Patent Application No. 29/484,069, filed on Mar. 5, 2014 and titled “CORRUGATED ELEMENTS FOR DEFINING LONGITUDINAL CHANNELS IN A BOAT FOR A DEPOSITION APPARATUS,” (“the '069 Design Application); (iii) U.S. Design Patent Application No. 29/482,760, filed on Feb. 21, 2014 and titled “HEXCELL CHANNEL ARRANGEMENT FOR USE IN A BOAT FOR A DEPOSITION APPARATUS,” (“the '760 Design Application”); and (iv) U.S. patent application Ser. No. 13/737,737, filed on Jan. 9, 2013 and titled “PRECURSOR SUPPLIES, MATERIAL PROCESSING SYSTEMS WITH WHICH PRECURSOR SUPPLIES ARE CONFIGURED TO BE USED AND ASSOCIATED METHODS,” (“the '737 Application”), in which a claim for the benefit of priority to U.S. Provisional Patent Application No. 61/585,150, filed on Jan. 10, 2012 and titled “PRECURSOR SUPPLIES, MATERIAL PROCESSING SYSTEMS WITH WHICH PRECURSOR SUPPLIES ARE CONFIGURED TO BE USED AND ASSOCIATED METHODS,” (“the '150 Provisional Application”) has been made pursuant to 35 U.S.C. §119(e).

The '628 Application claims the benefit of priority under 35 U.S.C. §119(e) to the '709 Provisional Application.

The entire disclosures of the '709 Provisional Application, the '067 Design Application, the '628 Application, the '643 Design Application, the '069 Design Application, the '760 Design Application, the '737 Application and the '150 Provisional Application are hereby incorporated herein.

### TECHNICAL FIELD

This disclosure relates generally to devices, systems (including material processing systems), and methods for forming protecting coatings. More particularly, embodiments of the present disclosure relate to devices, systems, and methods for selectively forming protective coatings, including moisture-resistant coatings, on substrates, such as electronic devices and their components. More particularly still, some embodiments of the present disclosure include a carrier system including a carrier and a plurality of cups configured to hold precursor material for introduction into a material processing system, such as material deposition equipment.

### RELATED ART

With the increased development of semiconductor technology, electronic devices have played an ever-increasing role in modern life. Mobile phones, digital cameras, digital media players, tablet computers, wearable electronic devices and the like are currently very common, and their use continues to expand. For example, mobile phones have become important equipment in the lives of an office worker, particularly with the advent of so-called smart phones which allow a person to not only make and receive phone calls, but also to send and receive email or other electronic messages, browse the Internet or other networks, view and create calendar events, view and edit documents, and the like. Mobile phones and other portable devices are also commonly used outside of an office setting; it is estimated that by the end of the year 2015, nearly and one billion smart phones will be produced every year.

As the use of portable electronic devices has increased, so has the likelihood that they will be damaged. In particular, unlike a desktop computer or other device with limited portability, a mobile device may be repeatedly subjected to different types of environments, it may be dropped or it may be subjected to other potentially damaging conditions. For instance, when carrying a smart phone, a laptop, an e-reader, a digital camera, a tablet computer, or another portable electronic device, the portable electronic device may be exposed to water from rain or other environmental conditions, or the device may accidentally be dropped into a puddle, sink, toilet, or another wet location.

Damage to an electronic device (portable or otherwise) may impair its functionality or may cause the electronic device to cease operating entirely. Electronic devices may be expensive to replace. In the context of mobile phones, mobile phone carriers may subsidize a portion of the purchase price of the mobile phone, but typically only provide the subsidy once every eighteen to twenty-four months. If the mobile phone is damaged prior to the time another subsidy will be provided by the mobile phone carrier, the user may have to bear the expense of replacing or repairing the mobile phone. Moreover, exposure of components of an electronic device to water or other types of moisture can also void the warranty on the electronic device, leaving a user with little choice but to do without the electronic device or to expend significant sums of money to repair or replace the electronic device.

Although removable cases have been developed for some portable electronic devices, removable cases often do not offer full protection against water, other types of moisture or other factors that may damage the portable electronic device. As a result, when a portable electronic device is exposed to water, other types of moisture or other sources of potential damage, the source of potential damage can find its way (e.g., leak, etc.) into the portable electronic device and damage components of the portable electronic device. Some protective cases may also make a device waterproof, but waterproof cases are often bulky and add significantly to the weight or size of the portable electronic device, taking away from the sleek appearance of the portable electronic device. In addition, waterproof cases are typically configured to prevent moisture from reaching the ports of a portable electronic device and, consequently, make it more difficult for a user to access and use the ports of the portable electronic device. For these and other reasons, many users avoid using waterproof cases.

As an alternative to the use of waterproof cases, moisture-resistance technologies have been developed for protecting the sensitive components within electronic devices. One example of such a technology is the parylene coating technology that has been developed by HZO, Inc. of Draper, Utah. Protective coating processes, like HZO's, may be integrated into assembly, refurbishing and remanufacturing processes, which are typically high-throughput, time-sensitive processes.

When protective coating processes are used, a precursor is often introduced into material processing equipment that is configured to apply the protective coating to one or more substrates. The precursor material may be carried by a boat, which is introduced into the material processing equipment. Sometimes the precursor material is heated to provide reactive species that will form the protective coating. When the precursor material is in a dry powder or particulate form, much of it may remain in the boat following the deposition processes. In many situations, the precursor material that remains is decomposed or otherwise affected in a way that precludes its use during a subsequent protective coating process.

SUMMARY

A carrier system in accordance with some embodiments of the present disclosure may be used within a material processing system, such as a deposition system (e.g., a parylene deposition system, etc.), to selectively apply a protective coating (e.g., a parylene coating, etc.) to a substrate. The carrier system, which may be configured to receive and hold precursor material (e.g., a parylene dimer, etc.), may include a carrier and one or more boats, or cups. The boats may be configured for positioning within the carrier and, thus, may be configured complementarily to at least a portion of the carrier. The carrier system may be configured (e.g., via its shape, its color, and/or its material) to enable it to heat to a desired temperature as quickly as possible. As an example, the carrier system may be shaped to ensure the cartridge is properly positioned and/or aligned within a vaporization chamber of a deposition system, to ensure the cartridge makes proper contact with a heat source of the vaporization chamber, and/or to optimize the overall area of the surface(s) that contact the heat source, which may provide for more efficient use of the precursor (e.g., may enable vaporization of substantially all of the precursor material within the cartridge, etc.) and may reduce damage to the precursor material or waste of the precursor material.

In one aspect, the carrier may include a two or more sections. An exterior of each section may include a peripheral surface and a bottom surface extending from the peripheral surface. The bottom surface of each section and of the entire carrier may, in some embodiments, be shaped complementarily to a receiving surface of a receptacle for the carrier in a material processing system (e.g., a heater of a vaporization chamber of a heat-assisted chemical vapor deposition system, etc.). In a specific embodiment, the bottom surface of the carrier, when its sections are assembled, may be semi-cylindrical in shape. Each section may further include an interior surface that defines a portion of one or more receptacles, each receptacle being configured to receive a cup. An interior portion of each receptacle may comprise a bottom surface. The carrier may comprise a thermally conductive material, for example only, aluminum, copper, gold, silver, or a combination thereof.

Each boat, which is configured to hold precursor material, may have a shape configured complementarily to the shape of its corresponding receptacle (e.g., cylindrical, a crescent shape, etc.). Each boat may have an exterior including a peripheral surface and a bottom surface extending from the peripheral surface.

Each boat may include a cell structure that defines a plurality of discrete columns, or cells, within an interior portion of the cup. The cell structure may be configured to separate a precursor material placed within the cup into a plurality of discrete portions. In some embodiments, the cell structure may comprise or be formed from a thermally conductive material; thus, the cell structure may serve as a thermal transfer device, distributing a desired temperature (e.g., heat, etc.) throughout the interior of the cup. According to one specific embodiment, a cross-section of each column of the plurality, taken transverse to a length of the column, may have a hexagonal shape.

The carrier system may further include one or more attachment features associated with the carrier and configured to secure a plurality of boats within the carrier. In some embodiments, the attachment features be configured for adjusting a tension between two or more sections of the carrier (e.g., longitudinal halves of the carrier, etc.). More specifically, an attachment feature may be positioned between adjacent sections of the carrier. In a more specific embodiment, the attachment features may comprise spring-loaded attachment features (e.g., spring-loaded pins and/or spring-loaded screws) and may be coupled to the carrier in alternating directions so as to substantially evenly distribute tension and tension vectors between adjacent sections of the carrier.

Other embodiments of the present disclosure include a carrier for introducing precursor material into a material processing system. The carrier may include a plurality of sections, each section including a receptacle configured for receiving a cup including precursor material. The carrier may further include a plurality of attachment features for adjusting a tension between two or more sections of the carrier.

Other embodiments of the present disclosure include cups for holding precursor material. A cup may include a peripheral surface and a bottom surface (e.g., a planar or substantially planar bottom surface, a curved bottom surface, etc.) extending from the peripheral surface. The cup may further include a cell structure positioned within an interior portion of the cup and defining a plurality of columns, or cells. The columns may divide a precursor material into sections in a manner that optimizes an efficiency with which the precursor material is processed (e.g., vaporized, etc.). Division of the precursor material may reduce or prevent damage of some precursor materials (e.g., agglomeration of a precursor to a parylene material, etc.). In some embodiments, the cell structure may provide for a substantially uniform temperature throughout the interior of the cup and, thus, throughout the contents of the cup (e.g., a precursor material). Each column of the heat transfer device may comprise any suitable shape. Some non-limiting examples include a hexagonal shape, a diamond shape, a triangle shape, and a square shape. According to a specific embodiment, a dimension across each column (e.g., its diameter, etc.) of may be about 0.5 inch or less. In a more specific embodiment, a distance across each column may be about 0.25 inch.

According to another embodiment of the present disclosure, a material processing system may include a vaporization chamber configured to receive one or more carrier systems, according to various embodiments of the present disclosure. The vaporization chamber may further include a heat source configured to heat the precursor material to a predetermined temperature or range of temperatures (e.g., a sufficient temperature to vaporize the precursor material, etc.). The material processing system may further include a pyrolysis tube and a deposition chamber. The pyrolysis tube may communicate with the vaporization chamber via a conduit and may be configured to heat vaporized precursor material to a temperature that will break, or “crack,” the vaporized precursor material into reactive species, or units (e.g., monomers, etc.). The deposition chamber may communicate with the pyrolysis chamber via another conduit and be configured to deposit the reactive species onto surfaces, including surfaces of one or more substrates, within the deposition chamber.

According to other embodiments, the present disclosure includes methods for operating a material processing system, such as a deposition system, for selectively applying a protective coating to a substrate. Various embodiments of such a method may include positioning one or more cups including precursor material within a carrier. Further, the method may include positioning the carrier including the one or more cups within a vaporization chamber. The method may further include heating precursor material within the one or more cups, vaporizing the same, as well as further processing that may enable application (e.g., deposition, etc.) of a protective coating onto a substrate.

Other aspects of the subject matter of this disclosure, as well as features and advantages of various aspects of that subject matter, will become apparent to those of ordinary skill in the art through consideration of the ensuing description, the accompanying drawings, and the appended claims.

### BRIEF DESCRIPTION OF THE DRAWINGS

In the drawings:

FIG. 1 is a side-view of a carrier system for holding and introducing a precursor material into a material processing system, such as material deposition equipment;

FIG. 2 is zoomed-in, side-view of the carrier system of FIG. 1;

FIG. 3 is a top-view of a carrier system for holding and introducing a precursor material into a material processing system, such as material deposition equipment;

FIG. 4 is a bottom-view of a carrier system for holding and introducing a precursor material into a material processing system, such as material deposition equipment;

FIG. 5 is another illustration of a carrier system including a carrier, a cup, and an attachment feature;

FIG. 6 is yet another illustration of a carrier system including a carrier, a plurality of cups, and an attachment feature;

FIG. 7 depicts a carrier system including a receptacle for receiving a cup;

FIG. 8 is a top-view of a carrier system including a receptacle for receiving a cup;

FIG. 9 is a perspective view of another embodiment of carrier according to this disclosure;

FIG. 10 shows a plurality of cups assembled with the carrier shown in FIG. 9;

FIG. 11 is a side view of the assembly shown in FIG. 10;

FIG. 12 is a top view of the assembly shown in FIG. 10;

FIG. 13 is a perspective view showing the assembly of FIG. 10 in an embodiment of an elongated receptacle of a material processing system (e.g., of a deposition chamber of a material deposition apparatus, etc.);

FIG. 14 is an end view of the assembly shown in FIG. 13;

FIG. 15 is a top-view of a cup for holding and introducing a precursor material into a material processing system;

FIG. 16 is a side-view of a cup for holding and introducing a precursor material into a material processing system;

FIG. 17 is a bottom-view of a cup for holding and introducing a precursor material into a material processing system;

FIGS. 18 and 19 depict an embodiment of a carrier for crescent-shaped cups; and

FIG. 20 schematically illustrates a material processing system with which a carrier system may be used.

### DETAILED DESCRIPTION

Devices, systems, and methods of the present disclosure include one or more elements for placing protective coatings on substrates. A few examples of substrates to which protective coatings may be applied include, but are not limited to, electronic devices or components thereof (e.g., portable electronic devices, wearable electronic devices, implantable electronic devices (e.g., medical devices, etc.), electronic devices used with industrial equipment, electronic devices used in aircraft, electronic devices used in automobiles, etc.), and other devices that are sensitive to moisture and/or contamination, medical devices, clothing, etc.

As used herein, a “substrate” may be a material, component, assembly, or other element to which a protective coating is applied. In accordance with some examples, the substrate may include one or more electronic components. As an example, a substrate including a single electronic component, or a combination of multiple electronic components, may be intended for use in an electronic device assembly that is itself all or a portion of an electronic device. The electronic device assembly may have one or more surfaces that could benefit from the application of a protective coating, including surfaces susceptible to damage if contacted by water or another type of moisture. Other examples of substrates include wearable electronic devices, implantable electronic devices, industrial electronic devices, electronic devices that are used in aircraft, vehicles and other types of equipment, etc.), medical devices and other devices that are sensitive to moisture and/or contamination. Aspects of the present disclosure relate to devices, systems and methods for applying a water-resistant or other protective coating to mitigate such susceptibility. In some cases, a water-resistant or other coating can be applied to interior components of an electronic device, whether prior to assembly or after assembly and subsequent disassembly.

The protective materials applied to surfaces of a substrate may impart at least a portion of the substrate with moisture resistance. As used herein, the term “protective coating” includes moisture resistant coatings or films, as well as other coatings or films that protect various parts of a substrate from moisture and/or other external influences. While the term “moisture resistant coating” is used throughout this disclosure, in many, if not all, circumstances, a moisture resistant coating may comprise or be substituted with a protective coating that protects coated components and/or features from other external influences. The term “moisture resistant” refers to the ability of a coating to prevent exposure of a coated element or feature to moisture. A moisture resistant coating may resist wetting or penetration by one or more types of moisture, or it may be impermeable or substantially impermeable to one or more types of moisture. A moisture resistant coating may repel one or more types of moisture. In some embodiments, a moisture resistant coating may be impermeable to, substantially impermeable to or repel water, an aqueous solution (e.g., salt solutions, acidic solutions, basic solutions, drinks, etc.) or vapors of water or other aqueous materials (e.g., humidity, fogs, mists, etc.), wetness, etc.). Use of the term “moisture resistant” to modify the term “coating” should not be considered to limit the scope of materials from which the coating protects one or more components of an electronic device. The term “moisture resistant” may also refer to the ability of a coating to restrict permeation of or repel organic liquids or vapors (e.g., organic solvents, other organic materials in liquid or vapor form, etc.), as well as a variety of other substances or conditions that might pose a threat to an electronic device or its components.

A protective coating may be applied selectively to some, but not all, portions of a substrate. For instance, an assembly may include multiple electronic components connected by one or more interfaces, ports, and the like. The protective coating could prevent or limit electrical contact between different components. Accordingly, the protective coating may not be applied where it would restrict electrical contact or other beneficial or otherwise desired connections or features. In accordance with some embodiments of the present disclosure, systems, methods and devices may be provided for selectively applying the protective coating to only desired portions of the substrate. In other embodiments, a protective coating may be applied to an entire surface of a substrate or to the entire substrate.

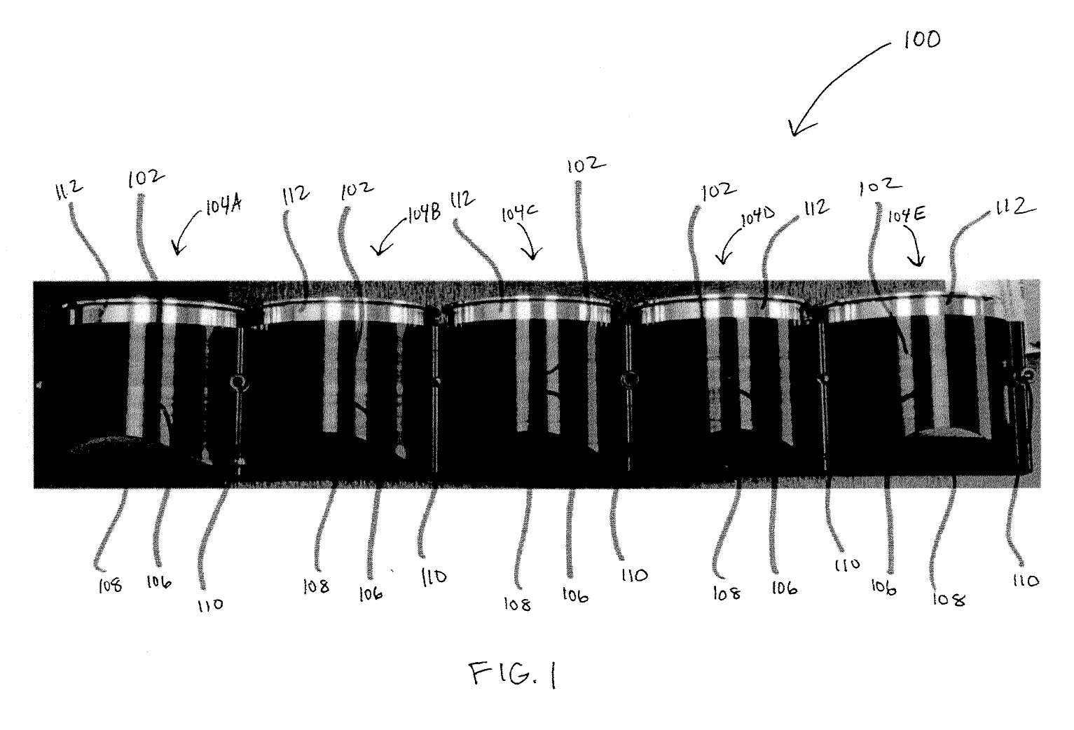

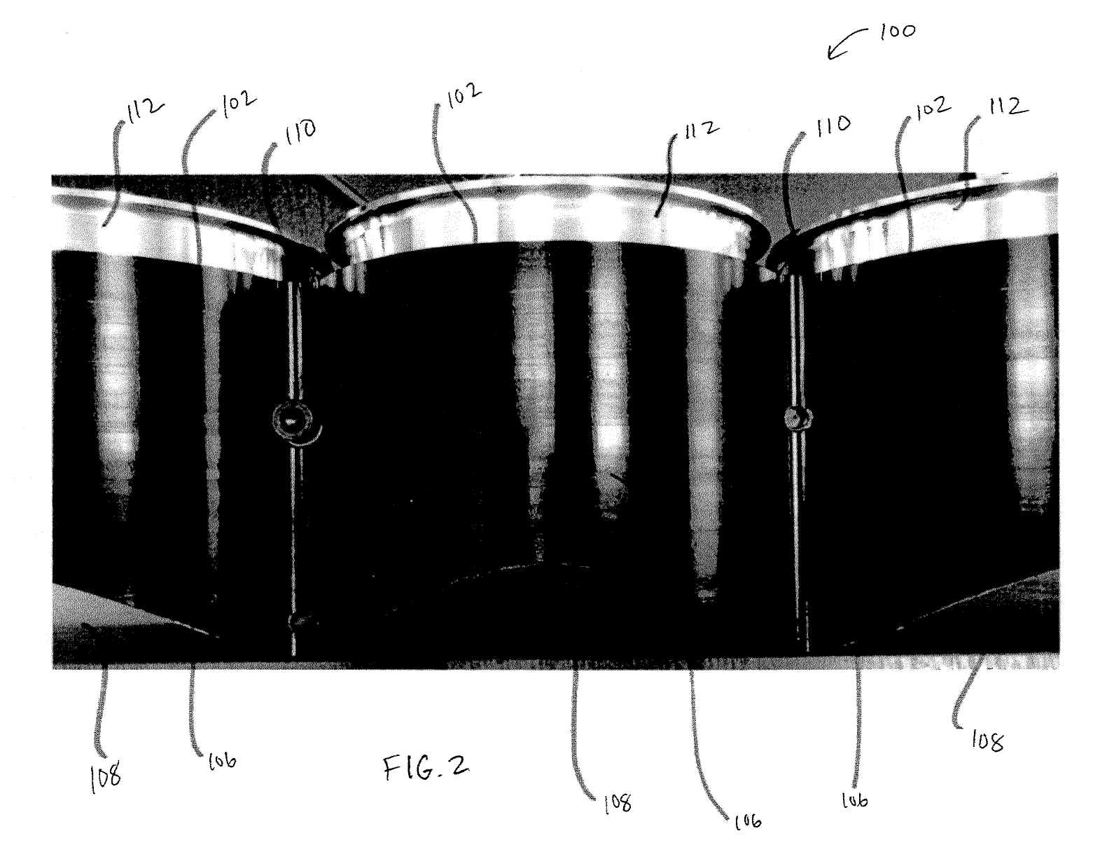

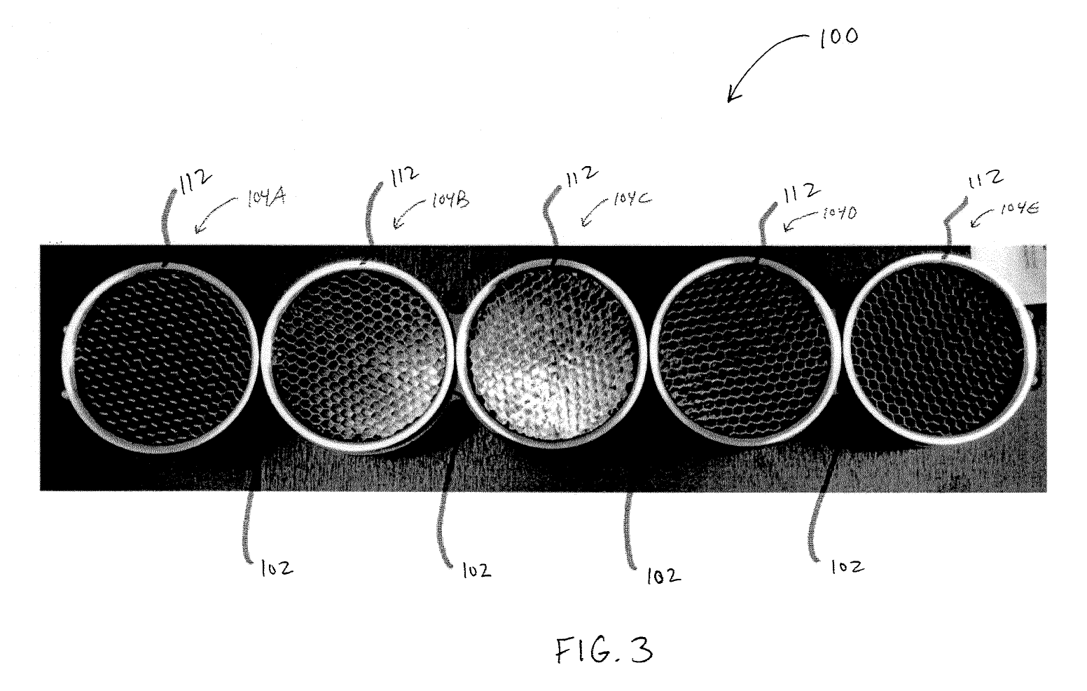

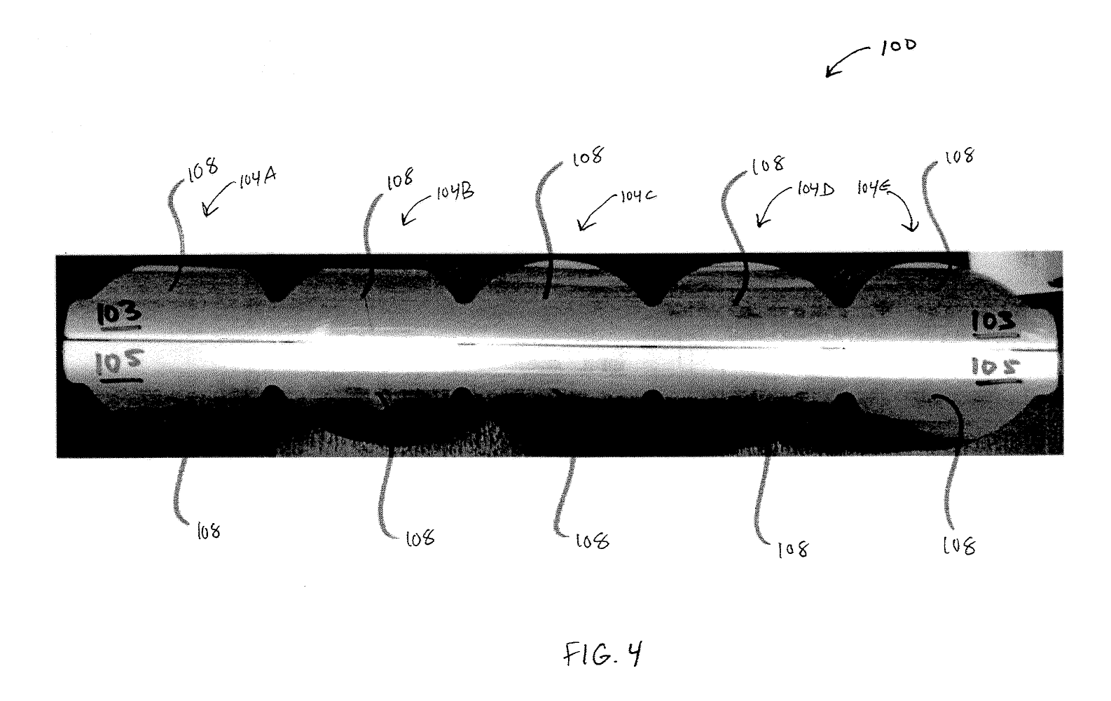

FIGS. 1-4 illustrate an embodiment of a carrier system 100 configured for holding and introducing a precursor material (e.g., a parylene dimer, etc.) into a material processing system. More specifically, FIG. 1 is a side-view of carrier system 100, FIG. 2 is a zoomed-in, side-view of carrier system 100, FIG. 3 is top-view of carrier system 100, and FIG. 4 is a bottom-view of carrier system 100. As will be described more fully below, carrier system 100 may be used within, for example, a deposition system or other material processing system for forming and/or applying a protective coating to one or more substrates. As described herein, carrier system 100 may be specifically configured to be received and engaged by a receptacle of a deposition system.

The carrier system 100, which may also be referred to herein as a “carriage system” and which may comprise a type of a so-called “boat” for introducing material into a material processing system, includes a carrier 102 including one or more sections 104A-104E, and one or more cups 112. The carrier 102, which may also be referred to herein as a “carriage”, includes an exterior with a peripheral surface 106 and a bottom surface 108 adjacent to and extending from peripheral surface 106. The cylindrical shapes of peripheral surface 106 may provide improved heat and/or temperature control and may enhance heat uniformity. The bottom surface 108, which may comprise, for example, a curved surface, is configured to maximize the surface area that will contact a heat source within the vaporization chamber of the deposition equipment. The shapes of the peripheral surface 106 and the bottom surface 108 of the carrier 102 may ensure that the carrier system 100 will be properly positioned within a receptacle of a vaporization chamber of a material deposition system and, in embodiments where a receptacle within the vaporization chamber is associated with or comprises a heat source, to ensure that carrier system 100 makes proper contact with the heat source of the vaporization system and/or that all precursor material within the cups 112 is within a certain distance of the heat source. Thus, the shapes of the peripheral surface 106 and the bottom surface 108 of the carrier 102 may be complementary to corresponding portions of the shapes of the receptacle of a vaporization chamber within which the carrier 102 is configured to be introduced.

It is noted that various features and characteristics of the carrier 102 (e.g., its shape, its material, it color, the use of attachment features 110) may be designed to enable the carrier 102 to heat to a desired temperature as quickly as possible. As an example, the carrier 102 may comprise a metal with good heat transfer rates. As a more specific example, the carrier 102 may comprise aluminum, copper, gold, silver, or any combination thereof. Further, according to one embodiment, the carrier 102 may be black in color (e.g., anodized aluminum, etc.), which may enhance heat absorption.

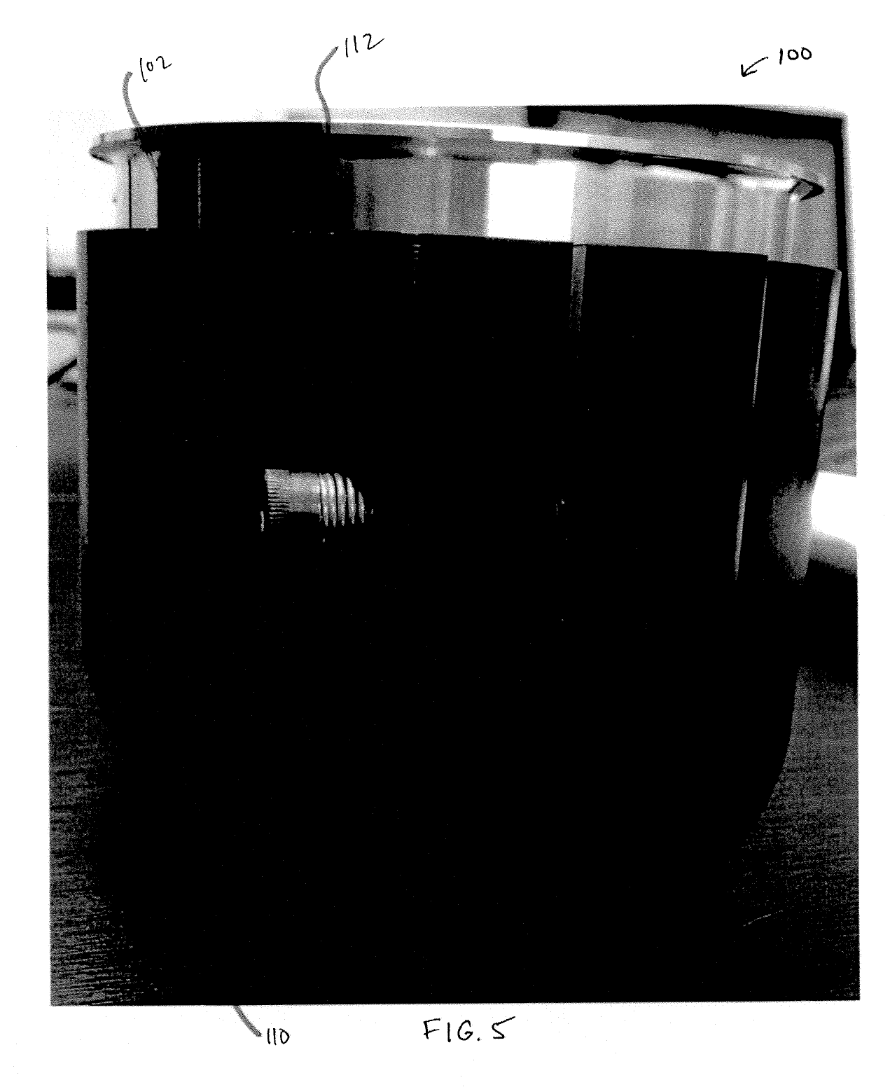

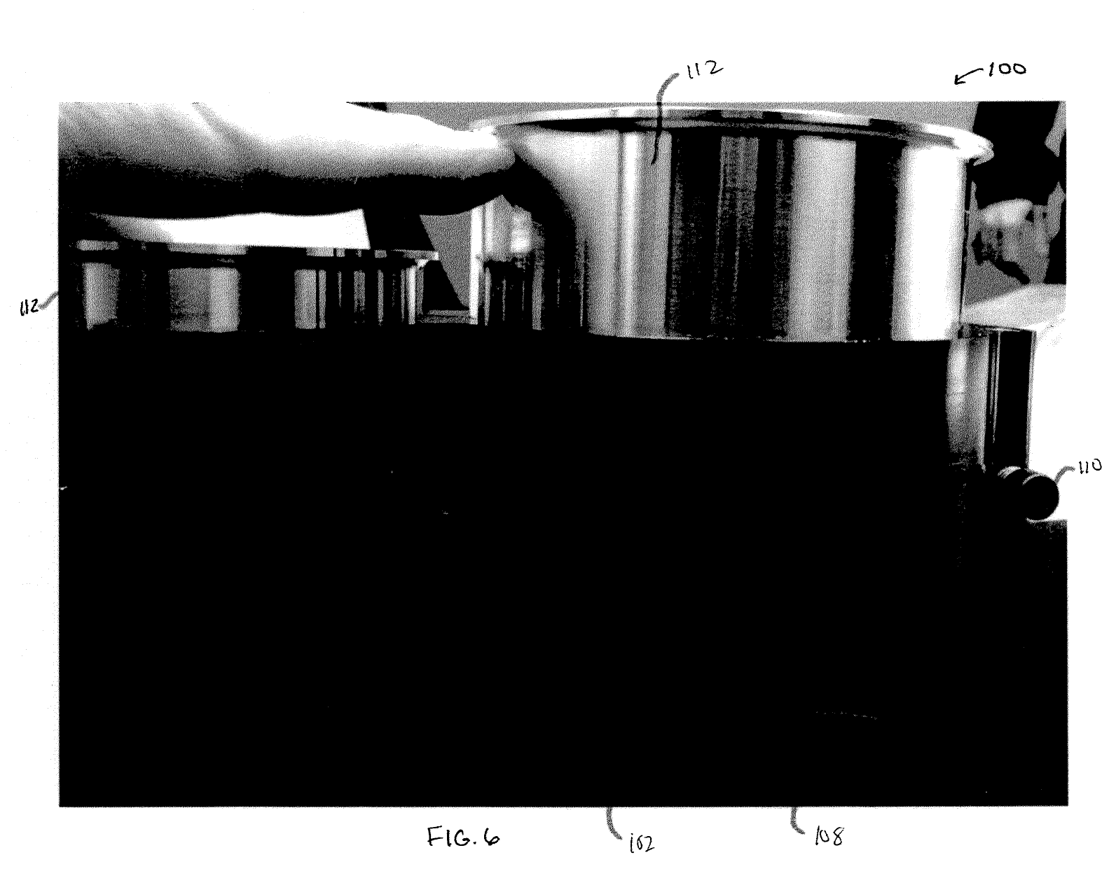

FIG. 5 illustrates a portion of the carrier system 100. More specifically, FIG. 5 illustrates an end of the carrier system 100 including the carrier 102, a cup 112, and an attachment feature 110, as will be described more fully below. FIG. 6 is another depiction of the carrier 102 showing the cups 112, which may be removably positioned within the carrier 102.

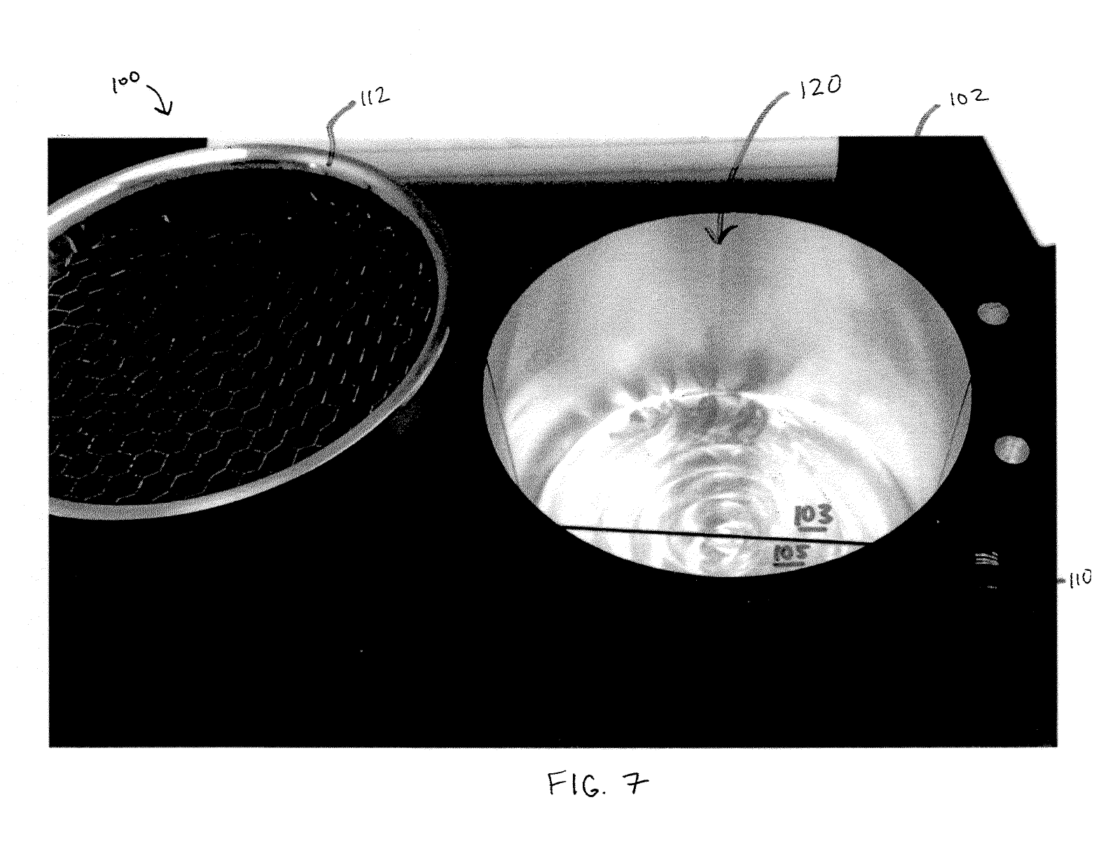

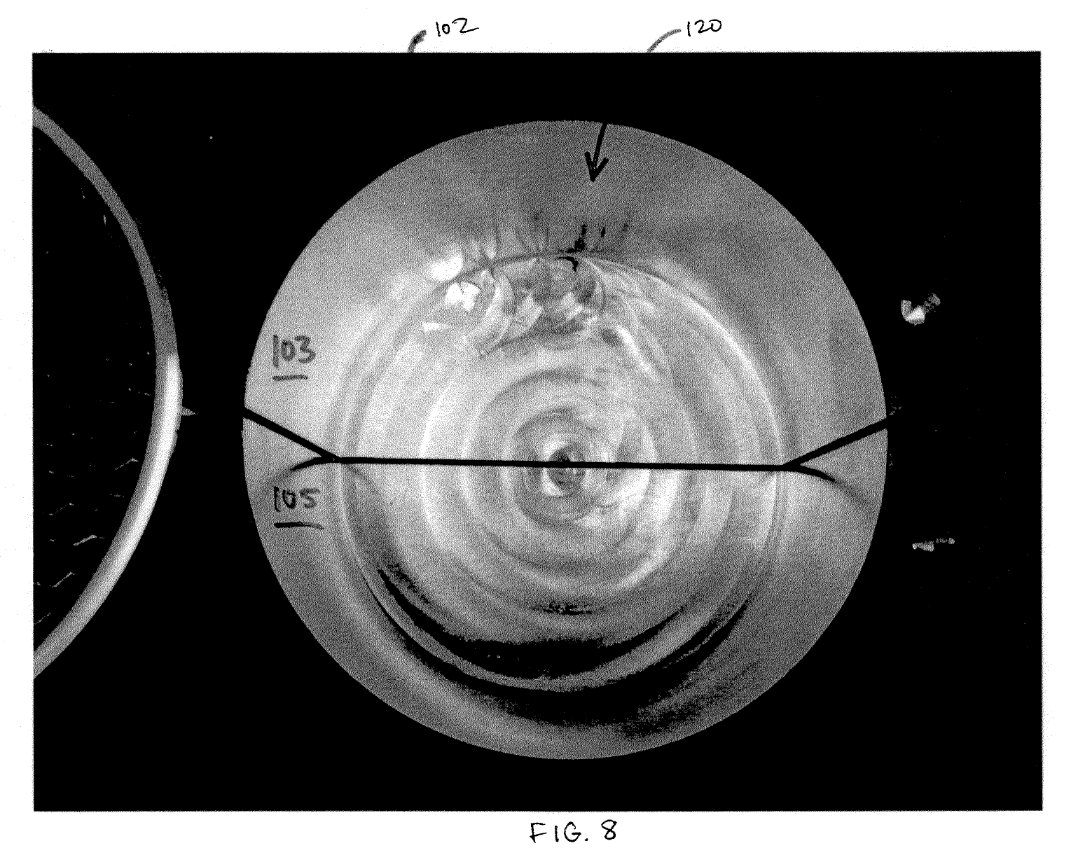

FIG. 7 illustrates a portion of the carrier system 100, including the carrier 102 and a cup 112. Further, FIG. 7 depicts a receptacle 120 of the carrier 102 configured for receiving the cup 112. FIG. 8 is another depiction of the carrier 102, including the receptacle 120. With specific reference to FIGS. 1, 7 and 8, each section 104A-104E of the carrier 102 may include one receptacle 120 for receiving a cup 112. Each receptacle 120 may have a cylindrical shape with a substantially planar bottom surface. As illustrated in FIGS. 4, 7 and 8, the carrier 102 includes two longitudinal halves 103 and 105 and, therefore, as will be appreciated by a person having ordinary skill in the art, each receptacle 120 is defined by the two longitudinal halves 103 and 105 of the carrier 102.

With reference again to FIGS. 1, 2 and 5-7, the carrier 102 may further include attachment features 110, which are positioned between adjacent sections 104 and enable adjustments in tension between the two longitudinal halves 103 and 105 of the carrier 102. More specifically, the attachment features 110 may comprise mechanical attachment features. Further, according to one embodiment, the attachment features 110 may be configured in alternating positions (i.e., each attachment feature is positioned in an opposite direction from each adjacent attachment feature) to provide for more uniform compression between the two longitudinal halves 103 and 105. By way of example only, the attachment features 110 may comprise spring-loaded attachment features. As a more specific example, the attachment features 110 may comprise spring-loaded pins configured to tightly clamp the two longitudinal halves 103 and 105 together. As yet another example, the attachment features 110 may comprise spring-loaded screws configured to enable adjustment of the tension between the two longitudinal halves 103 and 105. As will be appreciated, one or more attachment features 110 may be adjusted to reduce the tension between two longitudinal halves 103 and 105 to allow for removal of one or more cups 112 from an associated receptacle 120. Further, after positioning a cup 112 within a receptacle 120, one or more attachment features 110 may be adjusted to increase the tension between two longitudinal halves 103 and 105 for improved heat transfer.

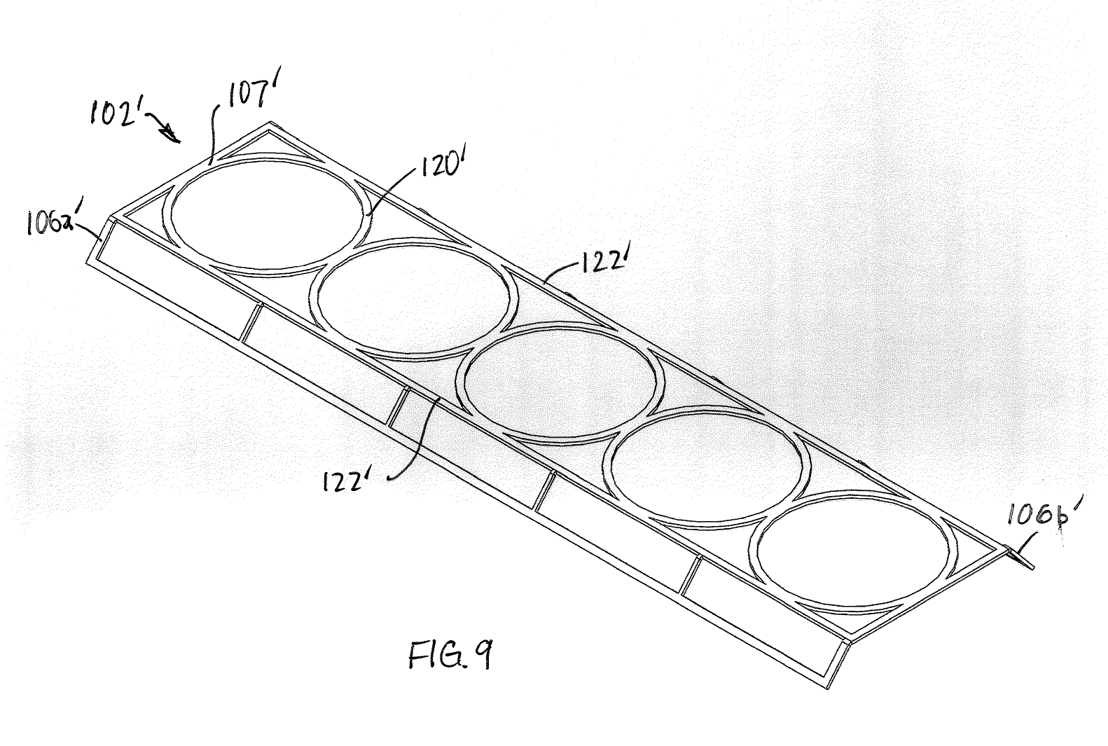

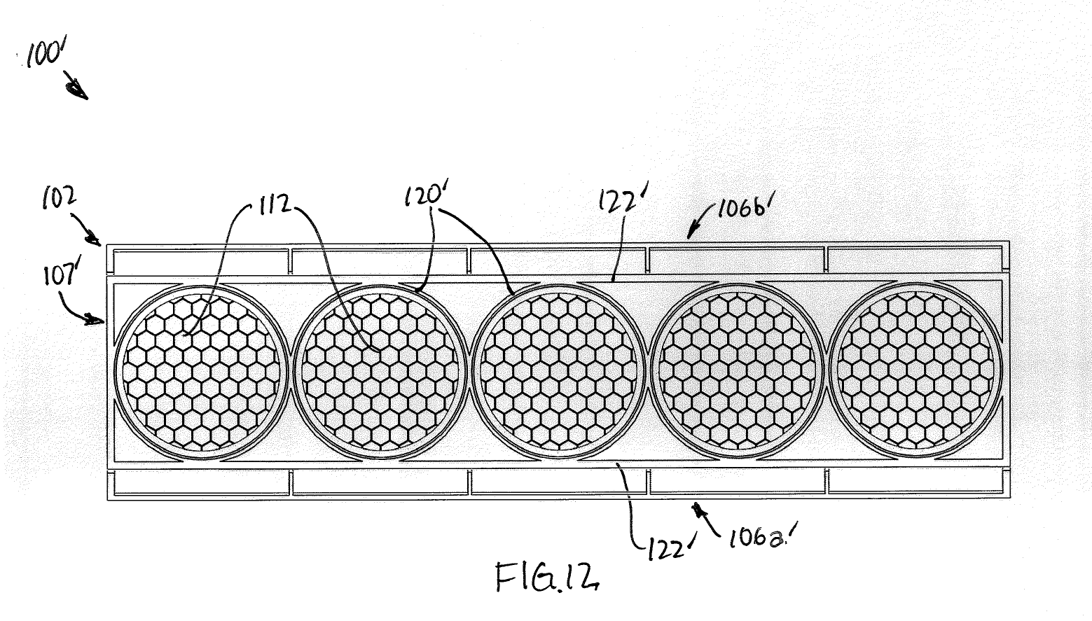

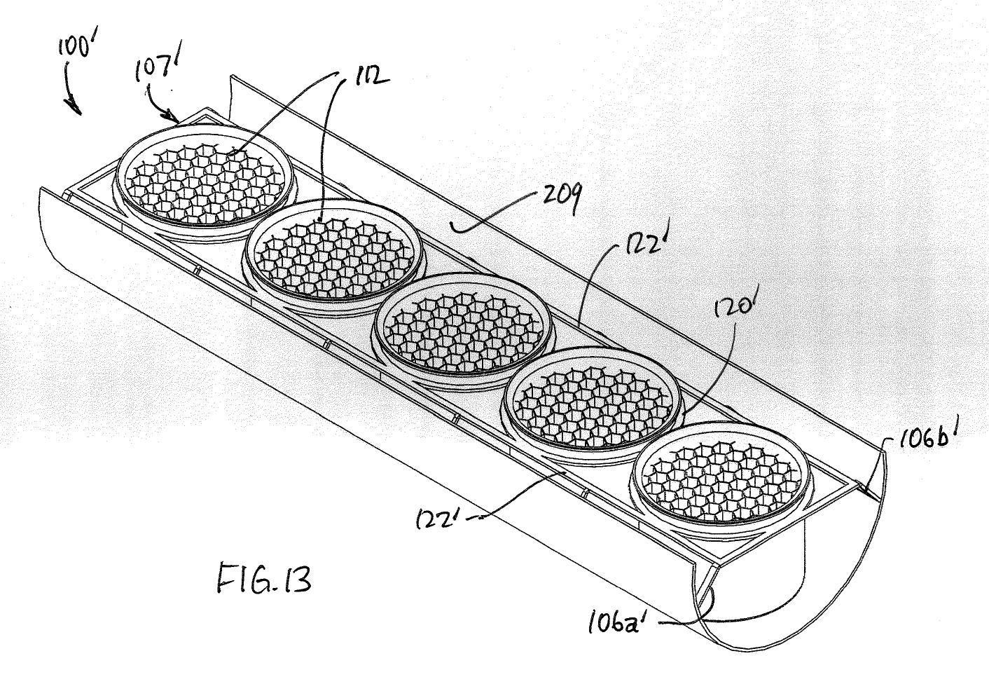

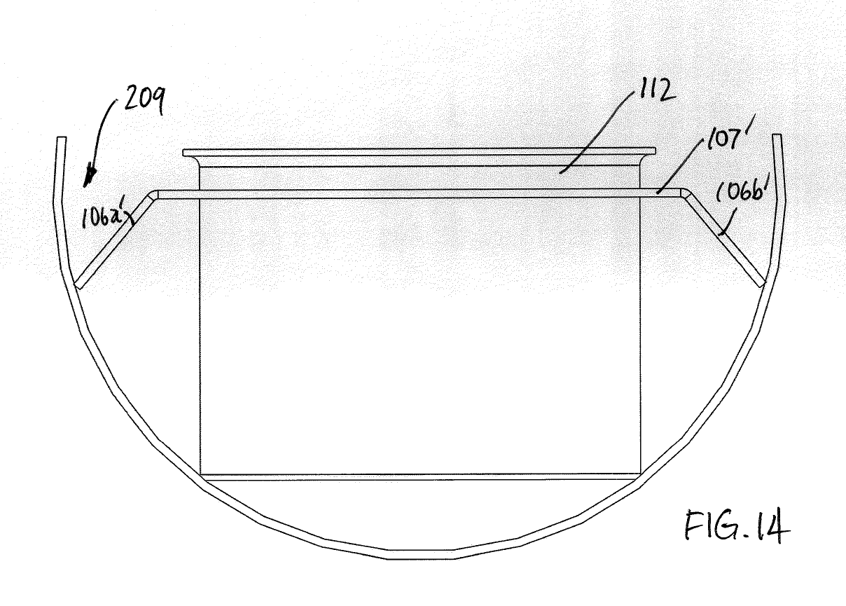

Turning now to FIGS. 9-14 another embodiment of a carrier system 100′ is depicted, with FIGS. 13 and 14 illustrating the carrier system 100′ within a semi-cylindrical receptacle of a vaporization chamber of a material processing system.

The carrier system 100′ includes a carrier 102′ that is configured to carry one or more cups 112. As depicted, the carrier 102′ may comprise a rack or frame that is configured to simultaneously introduce a plurality of cups 112 into a vaporization chamber of a material processing system. More specifically, the depicted embodiment of carrier 102′ includes a top element 107′ within which a plurality of receptacles 120′ are defined, with each receptacle 120′ being configured to receive a cup 112. The receptacles 120′ are aligned with one another along a length of the top element 107′, with the depicted embodiment including five receptacles 120′. In the specific embodiment depicted by FIGS. 9-12, the top element 107′ of the carrier 102′ comprises a frame, with each receptacle 120′ comprising a circular ring secured to a rectangular outer frame 122′ that defines an outer periphery of the top element 107′. More specifically, each receptacle 120′ may have a diameter that limits the range of diameters of cups that may be introduced therein and carried thereby. Accordingly, adapters may be used to enable such an embodiment of carrier 102′ to carry cups 112 with smaller diameters or widths. Cups 112 with other, non-circular shapes (e.g., ovals, octagonal prisms, square prisms, etc.) may also be introduced into and carried by the receptacles 120′, provided the dimensions of such cups 112 enable their introduction into the receptacles 120′ and enable them to be held by the receptacles 120′ as the carrier 102′ is lifted and/or moved from one location to another.

A peripheral element 106a′, 106b′ may protrude from each side of the top element 107′ of the carrier 102′. In the depicted embodiment, each peripheral element 106a′, 106b′ is defined by a plurality of elongated frame elements, although other embodiments of peripheral elements are also within the scope of this disclosure. As illustrated by FIGS. 13 and 14, each peripheral element 106a′, 106b′ may be configured and oriented to center the top element 107′ of the carrier 102′ and the cups 112 that are carried by the carrier 102′ within an elongated receptacle 209 of a vaporization chamber of a material processing system. In addition, the peripheral elements 106a′ and 106b′ may be oriented to position the top element 107′ and the tops of the cups 112 at a particular elevation within the elongated receptacle 209. In the illustrated embodiment, the peripheral elements 106a′ and 106b′ are oriented at angles that extend downwardly from the top element 107′. While the orientations of the peripheral elements 106a′ and 106b′ of the depicted embodiment of carrier 102′ position the top element 107′ at an elevation that will accommodate the heights of the illustrated cups 112, placing the top element 107′ at such an elevation will also enable the carrier to accommodate shorter cups 112 when placed within the elongated receptacle 209.

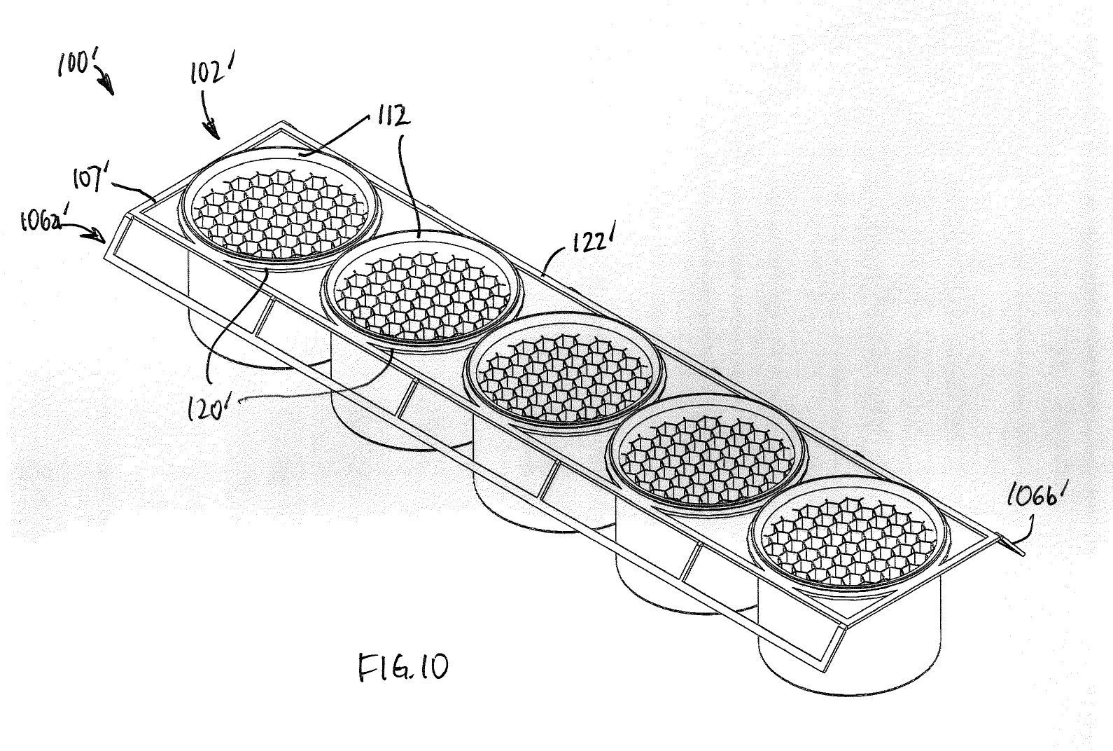

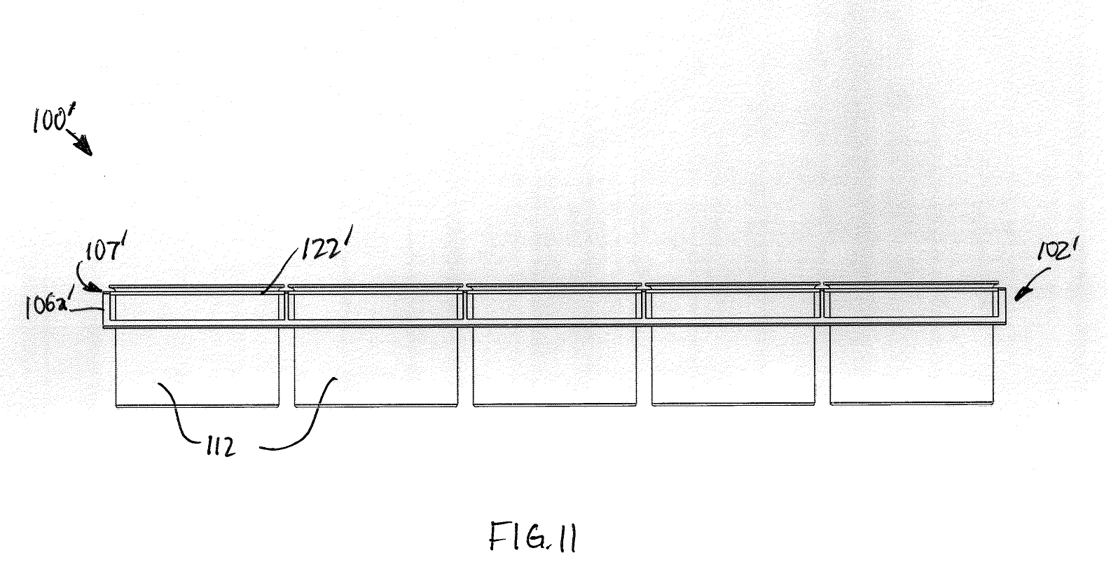

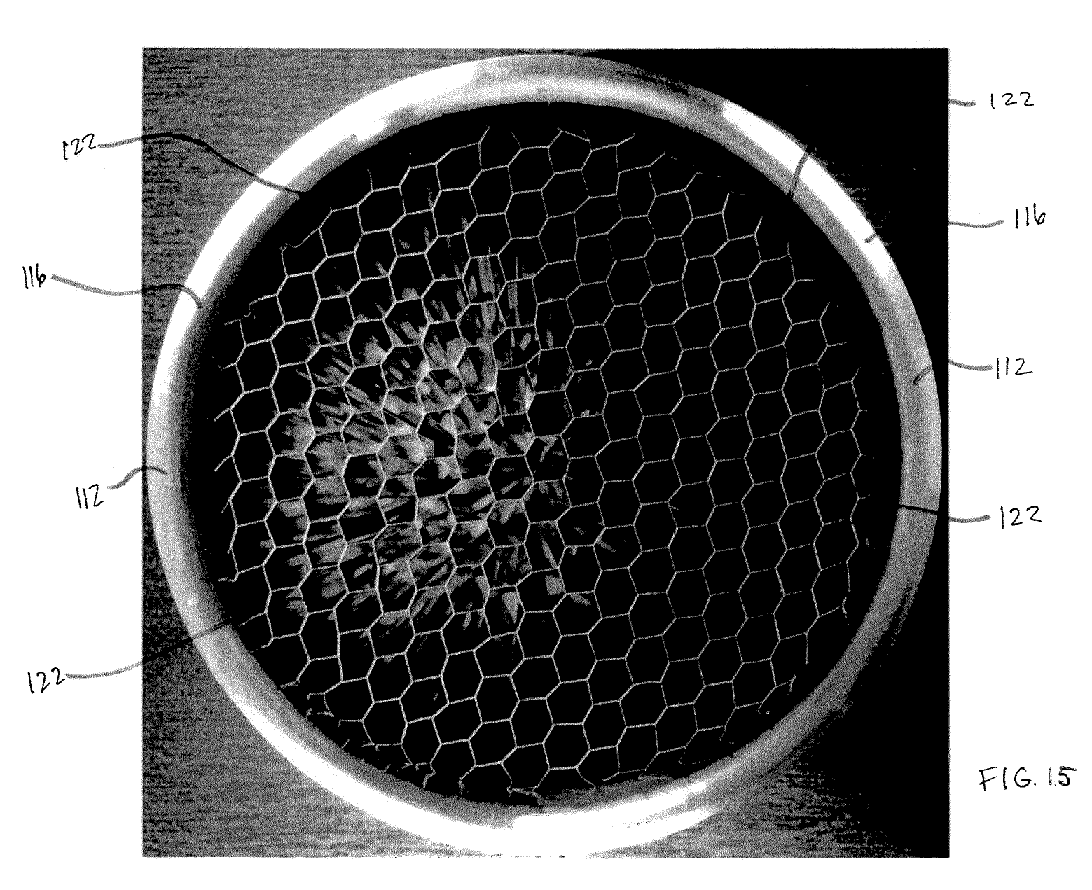

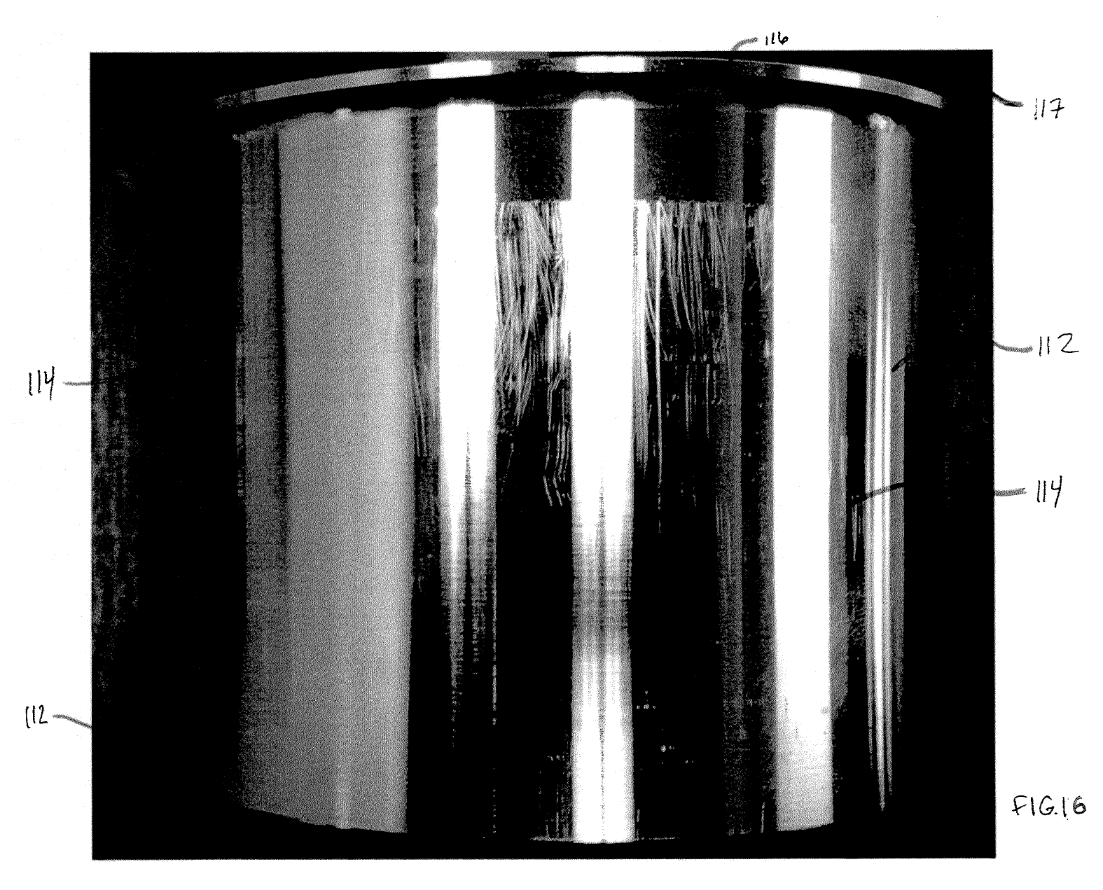

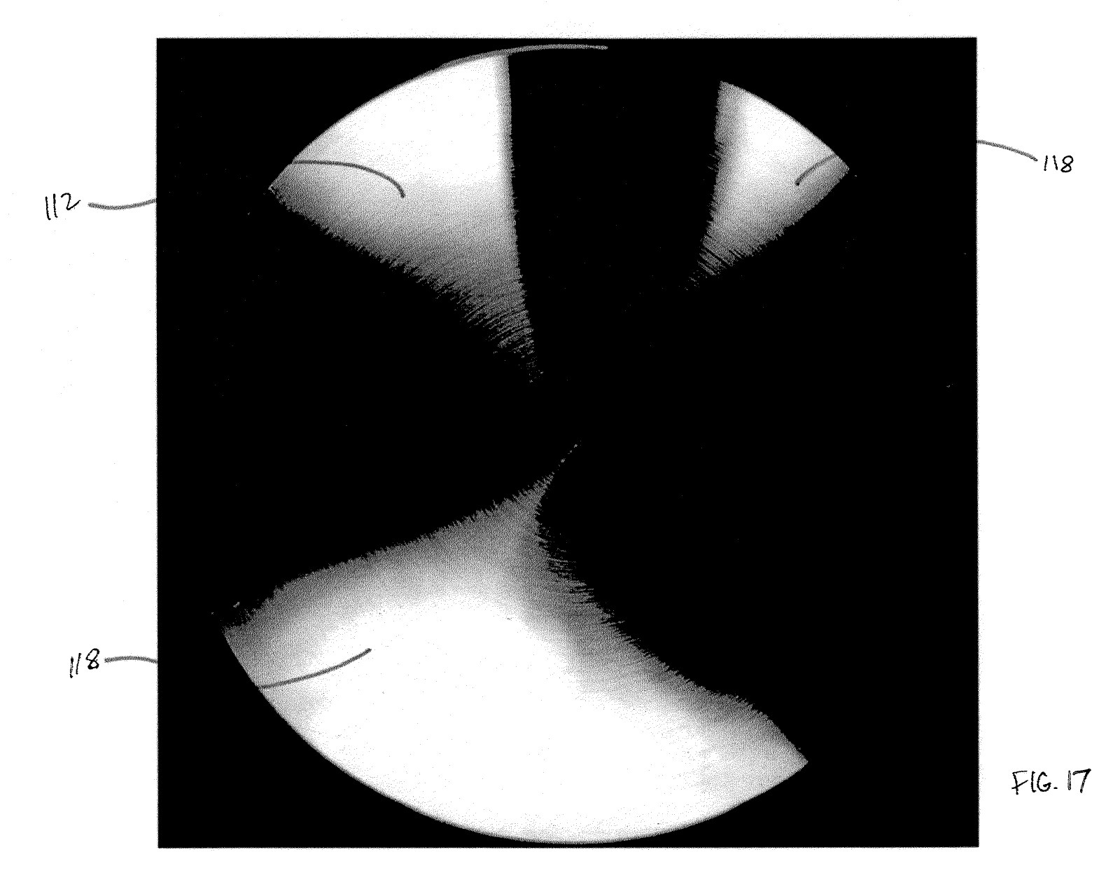

Further, FIGS. 15-17 are more detailed illustrations of an embodiment of cup 112. More specifically, FIG. 9 is a top-view of the cup 112, FIG. 10 is a side-view of the cup 112 and FIG. 11 is a bottom-view of the cup 112. Each cup 112 may be configured to receive and hold a precursor material, which may include precursor material of an organic material, any other material suitable for forming a protective coating, or any other material that serves as a precursor to a material that is to be applied to a substrate. In a specific embodiment, the precursor material may include a precursor (e.g., a dimer, etc.) to a parylene (i.e., an unsubstituted or a substituted poly(p-xylylene)).

As illustrated in FIGS. 15-17, cup 112 has a cylindrical shape and an exterior with a peripheral surface 114, a bottom surface 118 adjacent to and extending from peripheral surface 114, and a top surface 116. A transition between the top surface 116 and the peripheral surface 114 of the cup 112 may define a lip 117. The bottom surface 118 may be substantially planar surface or it may be curved. A substantially planar bottom surface 118 may provide a constant surface area as dimer is used and, therefore, the dimer may vaporize at a substantially constant rate. Further, the cylindrical shape of the illustrated embodiment of cup 112 may maximize direct contact with a heated surface of a carrier 102 (FIGS. 1-8).

While all of the cups 112 illustrated by FIGS. 15-17 have the same proportions (i.e., height:diameter), cups 112 of other proportions (e.g., shorter, taller, smaller diameters, larger diameters, etc.) are also within the scope of this disclosure. Other shapes of cups (e.g., polygonal prisms, elliptic cylinders, crescent shapes (e.g., as disclosed by U.S. patent application Ser. No. 14/445,628, filed on Jul. 29, 2014, the entire disclosure of which is hereby incorporated herein), etc.) are also within the scope of this disclosure, as are apparatuses that carry cups with non-cylindrical shapes.

A heat transfer element 122 may be positioned within an interior of each cup 112. The heat transfer element 122 may include a plurality of cells or columns and may be configured for transferring heat throughout the cup 112 and reducing, and possibly preventing, agglomeration of precursor material within the cup 112. The heat transfer device 112 may also be referred to herein as a “Hexcel.” As illustrated in FIGS. 3, 7, and 15, the heat transfer device 122 comprises a plurality of columns (also referred to herein as “cells”), wherein each column has the shape of a hexagonal prism. Utilizing a Hexcel may decrease a distance between a heat source and dimer, increase uniform temperature transfer, and enhance vaporization. More specifically, the cells increase the surface area of precursor material within the cup 112, or at least partially maintain the surface area of the precursor material by limiting the sizes of any clumps of the precursor material that are formed as the precursor material is heated. Since the cells extend vertically (or at least partially vertically), they may also increase the surface area and/or the number of physical paths that vaporized or sublimated precursor material may travel to escape the interior of the cup 112. Some embodiments of precursor materials may continue to form clumps or cakes in the cells, but in a smaller, more controlled fashion with a relative larger exposed area of precursor material, i.e., in separate cells, so that the clumps or cakes are less likely to block pathways for the vapor to escape. Thus, the cells may reduce or eliminate the likelihood that a precursor material will be heated in a manner that effectively reduces a surface area of the precursor material and, thus, reduces its volatilization (e.g., vaporization, sublimation, etc.) rate, or has any other detrimental effect on the usefulness of the precursor material. According to one embodiment, each column of the heat transfer device 122 may have a diameter of about 0.25 inch. It is noted that the heat transfer device 122 may comprise columns having shapes other than hexagons, such as square shapes, triangle shapes, diamond shapes and lemon shapes.

A heat transfer element 122 may comprise a thermally conductive material (e.g., steel, stainless steel, aluminum, a ceramic, etc.) that provides for efficient thermal communication with a heat-conductive surface of the cup 112.

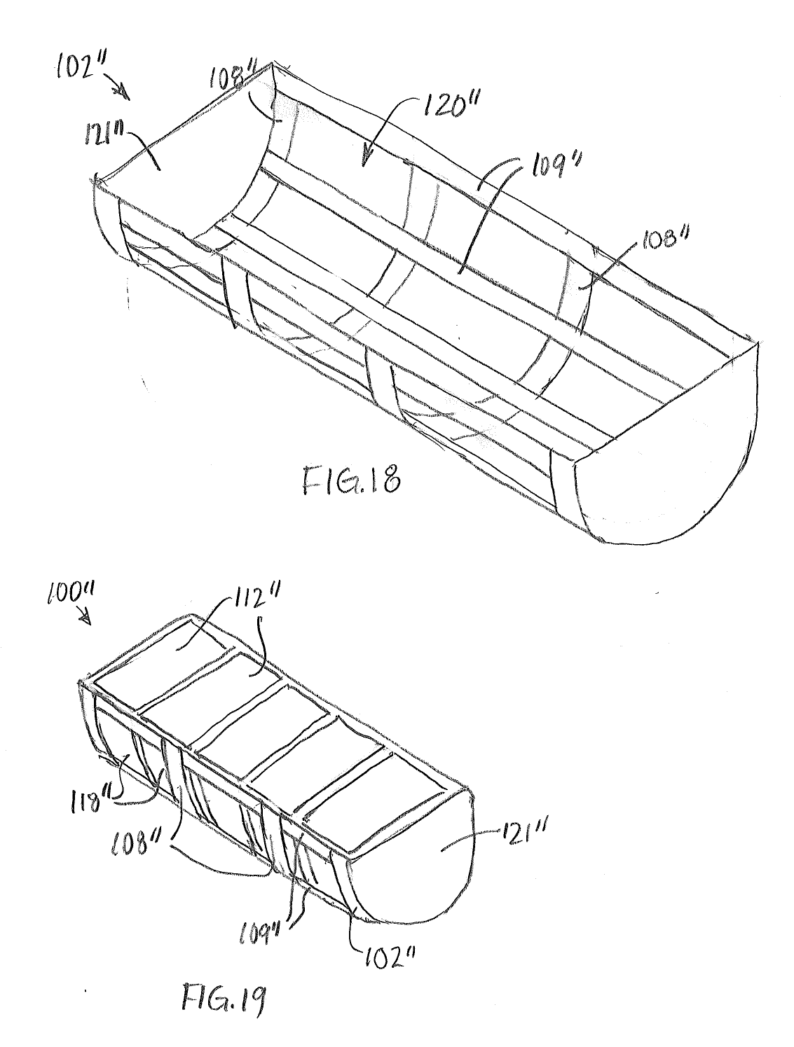

FIGS. 18 and 19 illustrate an embodiment of a carrier 102″ for holding a plurality of cups 112″ having crescent shapes. The carrier 102″ and the cups 112″ comprise a carrier system 100″. The carrier 102″ includes a receptacle 120″ for receiving the cups 112″. In the embodiment depicted by FIGS. 18 and 19, the carrier 102″ includes a plurality of shaped elements 108″ and a plurality of elongated elements 109″. Each shaped element 108″ includes an upper surface with a shape that complements a shape of the base 118″ of each cup 112″. The shaped elements 108″ may be spaced apart from one another. The elongated elements 109″ of the depicted embodiment are oriented longitudinally, across the spaced apart elements 108″. In some embodiments, the carrier 107″ may also include ends 121″. Together, the shaped elements 108″, the elongated elements 109″ and any ends 121″ define the receptacle 120″ of the carrier 102″. As an alternative to the frame-type embodiment of carrier 102″ depicted by FIGS. 18 and 19, a carrier may comprise solid surfaces, such as a hollow semi-cylindrical structure.

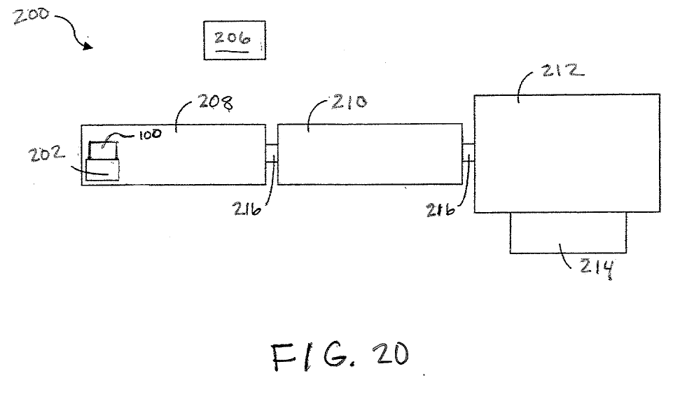

Reference is now made to FIG. 20, which depicts an embodiment of a material processing system 200 with which a carrier system 100, 100′, 100″ according to this disclosure may be used. The material processing system 200 includes a receiving device 202, which is also referred to herein as a “receptacle,” for receiving a carrier system 100, 100′, 100″. It is noted that the receiving device 202 may include one or more heat sources.

The receiving device 202 may be configured to only receive carrier systems of predetermined configurations. In some embodiments, the receiving device 202 may also be configured to define an orientation in which the carrier system 100, 100′, 100″ is introduced and, thus, to prevent improper orientation of the carrier system 100, 100′, 100″.

In a specific embodiment, such an apparatus may be configured to deposit a parylene coating onto a substrate. The embodiment of the material processing system 200 depicted by FIG. 20 includes a vaporization chamber 208, which communicates with, and is configured to receive a precursor material from the carrier system 100, 100′, 100″. A pyrolysis tube 210 is located downstream from vaporization chamber 208. Reactive species (e.g., parylene monomers) may be drawn from the pyrolysis tube 210 into a deposition chamber 212, which may communicate with a vacuum pump 214 and other elements, which may operate under control of a processing element (e.g., a computer, a microprocessor, etc.) to facilitate the deposition and polymerization of a parylene coating on a substrate. One or more valves 216, which may also operate under control of the processing element 206, may, along with the vacuum pump 214, control the flow of materials through the material processing system 200.

Various embodiments of apparatuses, systems and methods disclosed herein may improve the manner in which precursor materials are processed (e.g., vaporized, pyrolyzed, deposited, etc.). For example, an apparatus, system and/or method of this disclosure may provide for improved precision in process control, including control over process rates (e.g., uniform process rates, process rates that follow a predetermined profile, etc.). The disclosed apparatus, systems and/or methods may also enable processing (e.g., conformal coating of a large number of substrates, such as electronic components, electronic component assemblies, electronic devices, etc.).

Although the foregoing disclosure provides many specifics, these should not be construed as limiting the scope of any of the appended claims, but merely as providing information pertinent to some specific embodiments that may fall within the scopes of the claims. Other embodiments may be devised which lie within the scopes of the claims. Features from different embodiments may be employed in any combination. All additions, deletions and modifications, as disclosed herein, that fall within the scopes of the claims are to be embraced by the claims.

What is claimed:

1. A carrier system for holding precursor material, comprising:
a carrier including a plurality of sections, each section of the plurality including a receptacle; and
a plurality of cups for holding precursor material, wherein each cup of the plurality of cups is configured to be positioned within a receptacle of a section of the plurality of sections of the carrier.

2. The carrier system of claim 1, wherein each cup includes a cylindrical shape for be being positioned within a cylindrical receptacle of the carrier.

3. The carrier system of claim 1, the carrier including an exterior including a peripheral surface and a curved bottom surface extending from the peripheral surface.

4. The carrier system of claim 1, the carrier including a first longitudinal half including a first portion of each receptacle and a second longitudinal half including a second portion of each receptacle.

5. The carrier system of claim 4, the carrier further including a plurality of mechanical attachment features positioned between sections of the plurality of section and for attaching the first longitudinal half and second longitudinal half together and adjusting a tension between the first longitudinal half and second longitudinal half.

6. The carrier system of claim 1, the carrier further including a plurality of mechanical attachment features for adjusting a tension between a first longitudinal half and a second longitudinal half of an associated section of the plurality of sections.

7. The carrier system of claim 6, each attachment feature of the plurality of attachment features comprising one of a spring-loaded pin and a spring-loaded screw.

8. The carrier system of claim 6, wherein the plurality of attachment features are coupled to the carrier in alternating directions.

9. The carrier system of claim 1, the carrier comprising a black color.

10. The carrier system of claim 1, the carrier comprising at least one of aluminum, copper, gold, and silver.

11. The carrier system of claim 1, wherein each cup of the plurality of cups includes a heat transfer device including a plurality of columns, each column of the plurality of columns having at least one of a hexagon shape, a square shape, a triangle shape, and a diamond shape.

12. The carrier system of claim 1, wherein each cup of the plurality of cups includes a substantially planar bottom surface.

13. A cup for holding precursor material, comprising:
an exterior including a peripheral surface;
a bottom surface extending from the peripheral surface;
a heat transfer device positioned within an interior portion of the cup and including a plurality of columns.

14. The cup of claim 13, wherein each column of the plurality of columns has one of a hexagon shape, a square shape, a triangle shape, and a diamond shape.

15. The cup of claim 13, wherein each column of the plurality of columns has a diameter of substantially 0.25 inch.

16. The cup of claim 13, the bottom surface comprising a substantially planar surface.

17. A carrier for introducing precursor material into a material processing system, comprising:
a plurality of sections, each section of the plurality of sections including a receptacle configured for receiving a cup including precursor material; and
a plurality of attachment features for adjusting a tension between two longitudinal halves of the carriage.

18. The carrier of claim 17, each section of the plurality of sections comprising a cylindrical shape and including a peripheral surface and a curved, bottom surface extending from the peripheral surface.

19. The carrier of claim 17, each receptacle having a substantially planar, bottom surface for receiving a cup having a substantially planar, bottom surface.

20. The carrier of claim 17, each attachment feature the plurality of attachment features comprising a spring-loaded attachment feature.

21. A method, comprising:
positioning a plurality of cups including precursor material within a plurality of receptacles of a carrier;
positioning the carrier including the plurality of cups within a vaporization chamber of a deposition system; and
heating precursor material within the cups.

22. The method of claim 21, further comprising adjusting a tension between two longitudinal halves of the carrier via one or more attachment features coupled to the carrier.

23. The method of claim 21, wherein adjusting comprises one of decreasing the tension prior to positioning a cup of the plurality of cups within the carrier and increasing the tension after positioning a cup of the plurality of cups within the carrier.

24. The method of claim 21, wherein positioning a plurality of cups comprises positioning a plurality of cups including a plurality of heat transfer devices, each heat transfer device positioned within a cup and including a Hexcel.

25. The method of claim 21, wherein positioning a plurality of cups comprises positioning each cup of the plurality of cups having a substantially planar exterior bottom surface within a receptacle of the carrier having a planar bottom surface.

26. A material processing system, comprising:
a vaporization chamber including a carrier system for vaporizing precursor material, the carrier system comprising:
a carrier including a plurality of sections, each section of the plurality including a receptacle; and
a plurality of cups for holding precursor material, wherein each cup of the plurality of cups is configured to be positioned within a receptacle of a section of the plurality of sections of the carrier;
a pyrolysis tube coupled to the vaporization chamber and configured to heat vaporized precursor material to produce reactive species; and
a deposition chamber coupled to the pyrolysis tube and configured to deposit the reactive species onto one or more surfaces within the deposition chamber.
